(19) United States
(12) Patent Application Publication
(10) Pub. No.: US 2011/0284866 A1
(43) Pub. Date: Nov. 24, 2011

(54) LIGHT-EMITTING DIODE (LED) STRUCTURE HAVING A WAVELENGTH-CONVERTING LAYER AND METHOD OF PRODUCING

(76) Inventors: CHUONG A. TRAN, Baoshan Township (TW); Trung T. Doan, Baoshan Township (TW); Jui-Kang Yen, Taipei City (TW); Yung-Wei Chen, Taichung City (TW)

(21) Appl. No.: 13/191,235

(22) Filed: Jul. 26, 2011

Related U.S. Application Data
(63) Continuation-in-part of application No. 11/530,128, filed on Sep. 8, 2006, now Pat. No. 8,012,774.
Application No. 11/530,128 is a continuation-in-part of application No. 11/032,853, filed on Jan. 11, 2005, now Pat. No. 7,195,944.

(51) Int. Cl. H01L 33/42; H01L 33/40; H01L 33/50

(52) U.S. Cl. 257/76; 438/29; 257/98; 257/E33.064; 257/E33.068

(57) ABSTRACT

A light emitting diode (LED) device having a substantially conformal wavelength-converting layer for producing uniform white light and a method of making said LED at both the wafer and individual die levels are provided. The LED device includes a metal substrate, a p-type semiconductor coupled to the metal substrate, an active region coupled to the p-type semiconductor, an n-type semiconductor coupled to the active region, and a wavelength converting layer coupled to the n-type semiconductor.

### CROSS-REFERENCE TO RELATED APPLICATIONS

This application is a continuation-in-part of co-pending U.S. patent application Ser. No. 11/530,128, filed Sep. 8, 2006, which is a continuation-in-part of U.S. patent application Ser. No. 11/032,853, filed Jan. 11, 2005, now U.S. Pat. No. 7,195,944, which are both herein incorporated by reference in their entirety.

### BACKGROUND OF THE INVENTION

1. Field of the Invention

Embodiments of the present invention generally relate to a light-emitting diode and a method for fabricating the same.

2. Description of the Related Art

Advances in light emitting diode (LED) technology have resulted in LEDs with characteristics of small volume, light weight, high efficiency and long life. These LEDs have seen great advances in different monochromatic color output, such as red, blue and green. Single color LEDs can be used as a backlight in a special display, for instance, in mobile phones and light crystal displays (LCDs).

Recently, various attempts have been made to make white light sources by using light emitting diodes. Because the light emitting diode has an emission spectrum well-suited to generate monochromatic light, making a light source for white light requires arranging three light emitting components of red (R), green (G), and blue (B) near each other while diffusing and mixing the light emitted by them. When generating white light with such an arrangement, there has been the problem that white light of the desired tone cannot be generated due to variations in the tone, luminance, and other factors of the light emitting component. Also, when the LEDs are made of different materials, electric power required for forward biasing differs from one light emitting diode to another, making it necessary to apply different voltages to different light emitting components, which leads to complex drive circuitry. Moreover, because the light emitting components are semiconductor light emitting components, color tone is subject to variation due to differences in temperature characteristics, chronological changes, and operating environment. Unevenness in color may also be caused by failure to uniformly mix the light emitted by the light emitting components. Thus, LEDs are effective as light emitting devices for generating individual colors, but a satisfactory light source capable of emitting white light by using LEDs has not been obtained so far.

U.S. Pat. No. 5,998,925 discloses a white light emitting diode having a light emitting component that uses a semiconductor as a light emitting layer and a phosphor, which absorbs part of the light emitted by the light emitting component and emits light of a wavelength different from that of the absorbed light. The light emitting layer of the light emitting component is a nitride compound semiconductor, and the phosphor contains garnet fluorescent material activated with cerium—which contains at least one element selected from the group consisting of Y, Lu, Sc, La, Gd and Sm and at least one element selected from the group consisting of Al, Ga, and In—and is subject to less deterioration of its emission characteristics, even when used with high luminance for a long period of time.

FIG. 1 shows an LED as disclosed in the '925 patent. This LED is a lead-type LED having a mount lead 2 and an inner lead 4, wherein a light emitting component 8 is installed on a cup 6 of the mount lead 2, and the cup 6 is filled with a coating resin 14 that contains a specified phosphor to cover the light emitting component 8 and is molded in resin. An n-electrode and a p-electrode of the light emitting component 8 are connected to the mount lead 2 and the inner lead 4, respectively, by means of wires 12. In the LED constituted as described above, part of the light emitted by the light emitting component (LED chip) 8 (hereinafter referred to as LED light) excites the phosphor contained in the coating resin 14 to generate fluorescent light having a wavelength different from that of LED light, so that the fluorescent light emitted by the phosphor and the LED light that is output without contributing to the excitation of the phosphor are mixed and output. As a result, the LED also outputs light having a wavelength different from that of the LED light emitted by the light emitting component 8.

FIG. 2 shows a chip embodiment as disclosed in the '925 patent. The chip-type LED 26 is installed in a recess of a casing 22, which is filled with a coating material containing a specified phosphor to form a coating 28. The light emitting component 26 is fixed by using an epoxy resin or the like which contains Ag, for example, and an n-electrode and a p-electrode of the light emitting component 26 are connected to metal terminals 20 installed on the casing 22 by means of conductive wires 24. In the chip-type LED constituted as described above, similar to the lead-type LED of FIG. 1, fluorescent light emitted by the phosphor and LED light that is transmitted without being absorbed by the phosphor are mixed and output, so that the LED outputs light having a wavelength different from that of LED light emitted by the light emitting component 26. This type of conventional LED suffers from a color ring when used for emitting white light, whereby the color of the emitted light is bluer towards the middle and tends toward yellow at the edges near the casing 22.

U.S. Pat. No. 6,642,652 discloses a light source that includes a light emitting device—such as a III-nitride LED where Group 3 (III) includes such elements as Al, Ga, and In—covered with a luminescent material structure, such as a single layer or multiple layers of phosphor. Any variations in the thickness of the luminescent material structure are less than or equal to 10% of the average thickness of the luminescent material structure. In some embodiments, the thickness of the luminescent material structure is less than 10% of a cross-sectional dimension of the light emitting device. In some embodiments, the luminescent material structure is the only luminescent material through which light emitted from the light emitting device passes. In some embodiments, the luminescent material structure is between about 15 and about 100 microns thick. The luminescent material structure is selectively deposited on the light emitting device, for example, by stenciling or electrophoretic deposition.

An LED coated with phosphor according to the '652 patent is illustrated in FIG. 3. This LED includes an n-type region 44 formed on a substrate 42, such as sapphire, SiC, or a III-nitride material. An active region 46 is formed on the n-type region 44, and a p-type region 36 is formed on the active region 46. The n-type region 44, the active region 46, and the p-type region 36 are typically multilayer structures. Portions of the p-type region 36, the active region 46, and the n-type region 44 are etched away to expose a portion of n-type region 44. A p-type contact 34 is deposited on the p-type region 36, and an n-type contact 38 is deposited on the exposed portion of the n-type region 44. The LED is then flipped over and mounted to a sub-mount 30 by a material 32, such as solder. The luminescent material structure 40, such as phosphor, is deposited using electrophoresis to surround the LED at the individual die level.

U.S. Pat. No. 6,744,196 discloses thin film LED devices comprised of LED chips that emit light at a first wavelength and a tinted thin film layer over the LED chip that changes the color of the emitted light. For example, a blue-light emitting LED chip can be used to produce white light. The tinted thin film layer beneficially consists of ZnSe, CeO₂, Al₂O₃, or Y₂O₃Ce that is deposited using a chemical vapor deposition (CVD) process, such as metal organic chemical vapor deposition (MOCVD), atomic layer chemical vapor deposition (ALD), plasma enhanced MOCVD, plasma enhanced ALD, and/or photo enhanced CVD. As shown in FIG. 4, an n-contact 50 is positioned below a reflective layer 52. A tinted layer (a phosphor layer) 53 is positioned above the reflective layer 52. Next, a first passivation layer 54 is formed, and a p-type semi-transparent contact 56 is formed. A second passivation layer 58 is formed above the first passivation layer 54 and contact 56. A conductive wire 60 is connected to a p-pad 62, which is positioned above the p-lead 64.

Accordingly, what is needed is an improved semiconductor light source capable of emitting white light.

### SUMMARY

One embodiment of the invention provides a light emitting diode (LED) structure. The LED structure generally includes a metal substrate, a p-type semiconductor coupled to the metal substrate, an active region coupled to the p-type semiconductor, an n-type semiconductor coupled to the active region, and a wavelength-converting layer coupled to at least a portion of the n-type semiconductor.

Another embodiment of the invention provides a method for fabricating an LED structure. The method generally includes providing a semiconductor structure disposed on a wafer and coupled to a metal substrate, the semiconductor structure comprising a p-type semiconductor, an active region coupled to the p-type semiconductor, and an n-type semiconductor coupled to the active region; depositing an n-contact on a surface of the n-type semiconductor; applying a wavelength-converting layer above at least a part of the n-type semiconductor; and dicing the wafer into separate LED structures.

Yet another embodiment of the invention provides a method for fabricating an LED structure. The method generally includes providing a semiconductor structure coupled to a metal substrate and an n-contact, the semiconductor structure comprising a p-type semiconductor, an active region coupled to the p-type semiconductor, and an n-type semiconductor coupled to the active region; bonding a wire configured for external connection to the n-contact; and applying a wavelength-converting layer above at least a part of the n-type semiconductor.

Yet another embodiment of the invention is a method for fabricating an LED structure. The method generally includes providing a semiconductor structure (which typically includes a p-type semiconductor, an active region disposed above the p-type semiconductor, and an n-type semiconductor disposed above the active region) and attaching a pre-fabricated wavelength-converting layer above at least a portion of the n-type semiconductor. The method may further include dicing the semiconductor structure into separate LED structures.

Yet another embodiment of the invention provides an LED structure. The LED structure generally includes a p-type semiconductor, an active region disposed above the p-type semiconductor, an n-type semiconductor disposed above the active region, and a wavelength-converting layer disposed above at least a portion of the n-type semiconductor, wherein an upper surface of the wavelength-converting layer is substantially flat.

Yet another embodiment of the invention provides an LED structure. The LED structure generally includes one or more metal layers, a p-type semiconductor coupled to the metal layers, an active region coupled to the p-type semiconductor, an n-type semiconductor coupled to the active region, and a wavelength-converting layer coupled to at least a portion of the n-type semiconductor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1-4 are cross-sectional schematic representations of prior art light-emitting diode (LED) structures;

FIGS. 5A-B are cross-sectional schematic representations of an LED with a wavelength-converting layer in a normal and an exploded view according to one embodiment of the invention;

FIG. 6 is a process diagram depicting a method of applying a wavelength-converting layer to a wafer according to one embodiment of the invention;

FIG. 7 is a process diagram depicting a method of applying a wavelength-converting layer to a wafer according to one embodiment of the invention;

FIG. 8 is a process diagram depicting a method of applying a wavelength-converting layer to an individual light emitting device at the die level according to one embodiment of the invention;

FIG. 9 is a graph of the optical spectrum of a forward biased LED according to one embodiment of the invention; and

FIG. 10 is a flow diagram of example operations for attaching a pre-fabricated wavelength-converting layer to a semiconductor structure according to one embodiment of the invention.

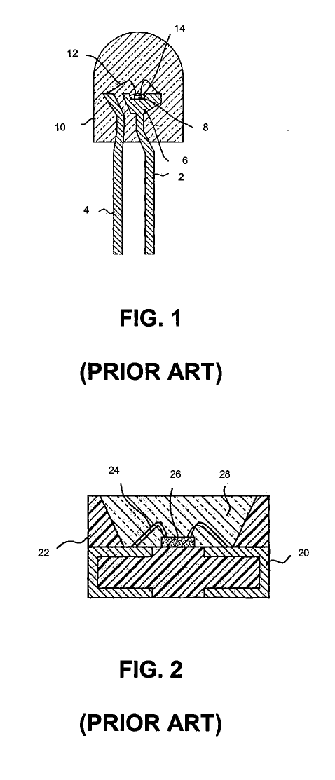

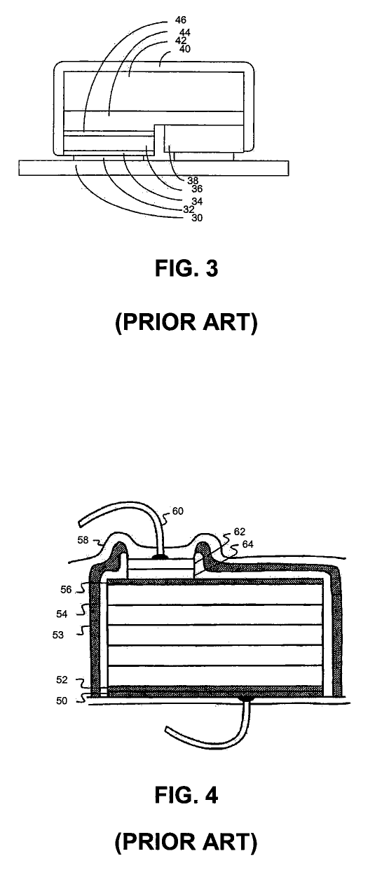

### DETAILED DESCRIPTION

Embodiments of the present invention provide a light emitting diode (LED) device having a substantially conformal wavelength-converting layer for producing uniform white light and a method of making said LED at both the wafer and individual die levels.

### An Exemplary LED Structure

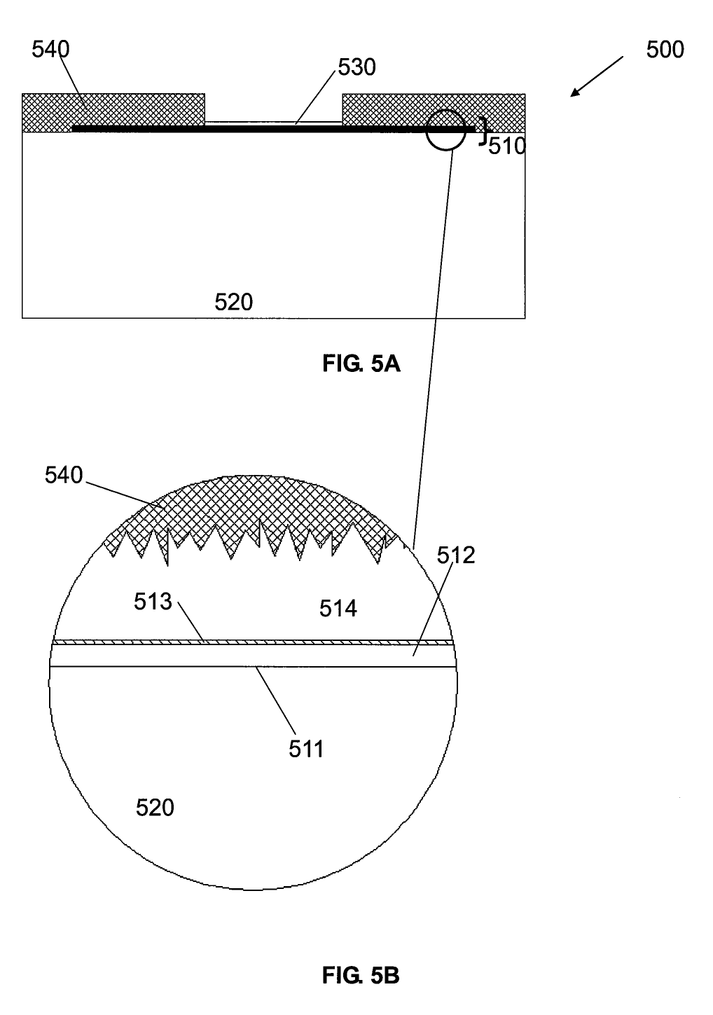

FIG. 5A depicts an exemplary structure of one embodiment of an LED device 500. The LED device 500 may include a semiconductor structure 510 disposed above a metal substrate 520. The metal substrate 520 may comprise a single layer or multiple layers of any suitable metal or metal alloy, such as Ag, Al, Au, Pd, Pt, Ni, Cu, Ti, or any combination thereof. The metal substrate 520 may be formed by electrochemical or electroless chemical deposition.

Comprising a p-type region 512, an active region 513, and an n-type region 514, the semiconductor structure 510 may be initially formed by depositing a multilayer epitaxial structure above a suitable carrier substrate (not shown), such as sapphire or SiC. The carrier substrate may be removed after the formation of the metal substrate 520, and removal may be accomplished according to any of several methods including the use of a laser, etching, grinding/lapping, chemical mechanical polishing, or wet etching, among others. For example, a sapphire carrier substrate may be removed using a laser lift-off (LLO) technique for some embodiments, while other embodiments may use etching to remove a SiC carrier substrate.

The details of the semiconductor structure 510 may be seen in the exploded view of FIG. 5B. A p-type semiconductor region 512 may be positioned above the metal substrate 520 and may comprise p-GaN. A reflective layer 511 may be interposed between the metal substrate 520 and the p-type region 512 in an effort to direct the emitted light from the LED device 500 in a single general direction, thereby improving luminous efficiency. The reflective layer 511 may contain suitable materials for reflecting light, such as Ag, Al, Ni, Pd, Au, Pt, Ti, Cr, Vd, or alloys of these metals. A light-emitting active region 513 (including a multi-quantum well) may be formed above the p-type region 512. The active region 513 may comprise AlₓIn_{y}Ga_{1-x-y}N, where 0≦x≦1 and 0≦y≦1−x, and may emit light having a wavelength between 200 nm and 480 nm when the device 500 is forward biased.

An n-type semiconductor region 514 may be formed above the active region 513 and may comprise n-GaN. As shown in FIG. 5B, the surface of the n-type region 514 may be roughened in an effort to improve light extraction. The roughening of the surface of the n-type region 514 may be accomplished using any suitable method, including wet etching, dry etching, and photolithography with etching. An n-contact 530 may be formed above the surface of the n-type region 514. A wavelength-converting layer 540 may cover at least part of the surface of the n-type region 514.

The metal substrate 520 may be deposited using electrochemical deposition, electroless chemical deposition, chemical vapor deposition (CVD), metal organic CVD (MOCVD), plasma enhanced CVD (PECVD), atomic layer deposition (ALD), physical vapor deposition (PVD), evaporation, plasma spray, or suitable combinations of these techniques. The metal substrate 520 may be single or multi-layered. For some embodiments, Ag/Pt, Ag/Pd, or Ag/Cr may compose the first layer, Ni may compose the second layer potentially used as a barrier layer, and Au may compose the third layer. Other suitable metals, such as W, Cu, or Ni may also compose the third layer. In other embodiments, the metal substrate 520 may comprise three layers. A first layer (composed of Ag, Al, Pt, Ti, or Cr, for example) may be deposited, and then a second layer comprising materials such as TiN, TaN, TiWN, and TiW with oxygen as a barrier may be formed above the first layer. The third layer may comprise suitable conductive materials, such as Au, W, Cu, Ni, and other metals, and may be formed above the second layer.

Regarding the wavelength-converting layer 540, its purpose may be to accept light emitted from the active region 513 of the LED at one wavelength and emit light at a different wavelength, thereby producing a different color of light. As such, the wavelength-converting layer 540 may comprise a fluorescent material, such as phosphor, in an effort to emit white light from other colors generated by the active region 513. For some embodiments, the wavelength-converting layer 540 may comprise a single layer of phosphor and a binding material. Other embodiments may include a first transparent layer (not shown) that may comprise any suitable materials, such as a passivation layer or silicon dioxide, silicon nitride, titanium oxide, aluminum oxide, indium tin oxide (ITO), or polymer materials, and a second layer of phosphor and a binding material.

### Exemplary Wavelength-Converting Layer Formation Methods At the Wafer Level

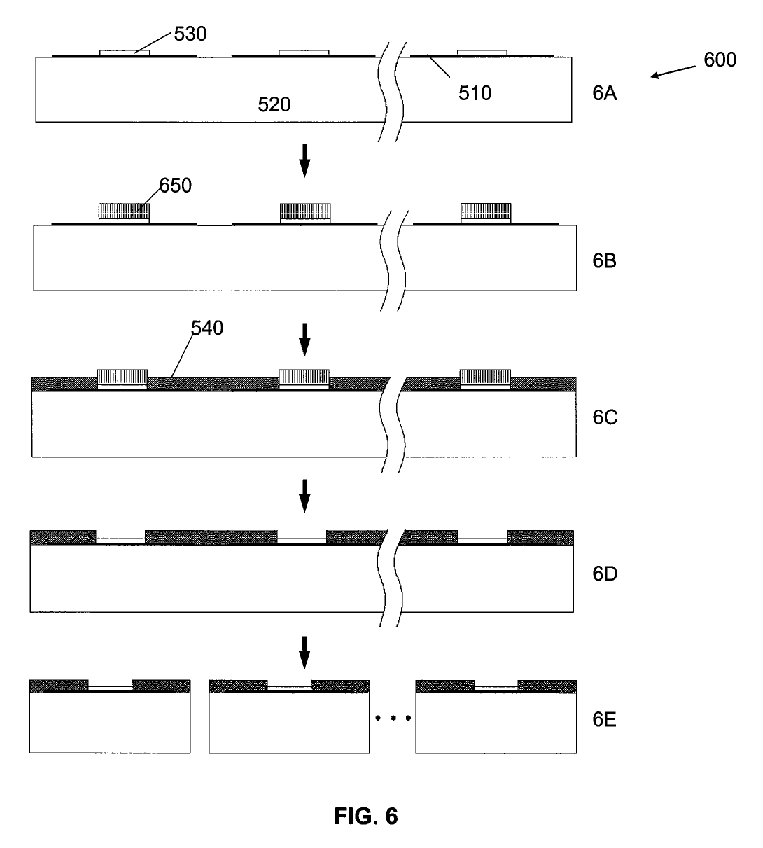

FIG. 6 illustrates a method of forming the wavelength-converting layer 540 at the wafer level. After the LED semiconductor structure 510 has been formed on the carrier substrate, the metal substrate 520 has been formed, the carrier substrate has been removed, and n-contacts 530 have been added to the dies on the wafer 600 (6A), a temporary material, such as a photoresist 650, may be applied to the n-contacts 530 using a suitable method, such as lithography (6B). Next, the wavelength-converting layer 540 may be formed above the surface of the n-type semiconductor region 514 (6C). For some embodiments, all of the areas not covered by the photoresist layer 650 may be filled in with the wavelength-converting layer 540 on the surface of the wafer 600. However, care should be taken so that the height of the wavelength-converting layer 540 remains below the height of the photoresist layer 650.

Any of several methods may be employed to apply the wavelength-converting layer 540. For some embodiments, the wavelength-converting layer 540 may be formed using a spin coater. The spin coater may be operated between 500 to 30,000 rpm in an effort to control the layer thickness on the LED wafer 600. Although the spin coat method is preferable in an effort to obtain a predetermined equal film thickness, other methods, such as screen printing, dispensing, spray coating, inject printing, a roller method, or a dipping method, may be exercised. As shown in FIG. 6, the wavelength-converting layer 540 with substantially equal thickness has a flat upper surface, and, therefore, may have a rectangular cross-section.

To make the substance of the wavelength-converting layer 540, a mixture of phosphor powder and a binding material may be prepared. The phosphor powder may be surface-treated during the manufacturing process in an effort to improve the dispersing property and adhesion thereof. The binding materials may comprise silicone, epoxy, acrylic, or spin-on glass. The thickness of the wavelength-converting layer 540 may be reproducibly tuned by the mixture's viscosity and spin rate to change the resulting CIE (International Commission on Illumination) coordination of the LEDs to produce white light.

After the wavelength-converting layer 540 is formed on the wafer 600, the wafer 600 may be baked. The baking method is not limited as long as the moisture content of the wavelength-converting material is evaporated. Thus, various methods using a heater, an oven, dried air, or surface treatment such as a radiant heat lamp may be employed. After baking the wavelength-converting layer 540, the wavelength-converting layer 540 may be patterned in an effort to improve light extraction, and the photoresist layer 650 may be removed (6D). Then, the LED die on the wafer 600 may be diced and separated into individual components (6E).

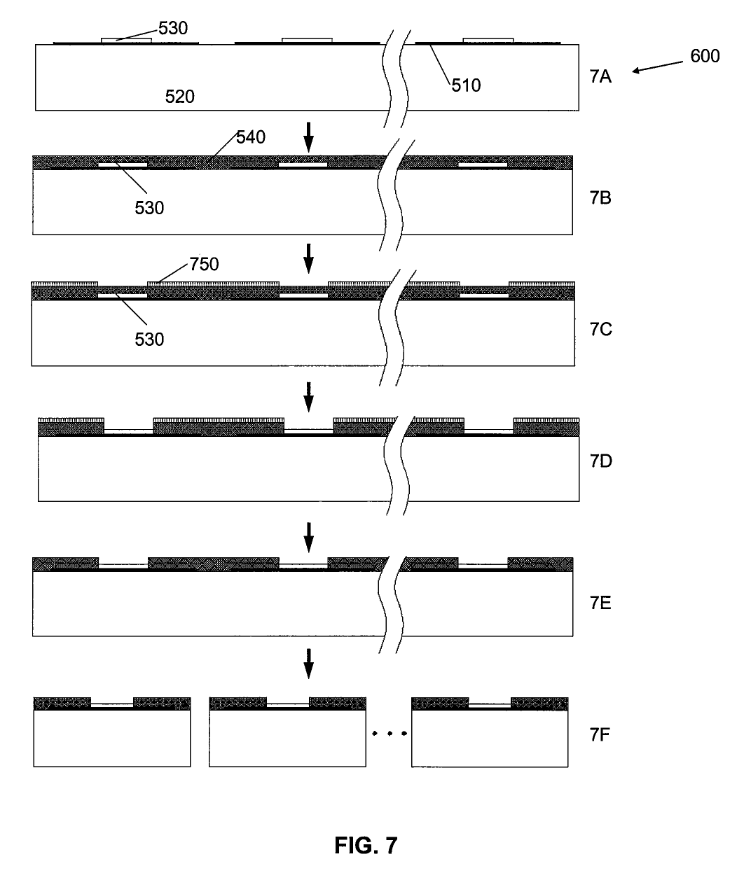

FIG. 7 shows another method of applying the wavelength-converting layer 540 at the wafer level according to some embodiments of the invention. After the LED semiconductor structure 510 has been formed on the carrier substrate, the metal substrate 520 has been formed, the carrier substrate has been removed, and n-contacts 530 have been added to the dies on the wafer 600 (7A), the wavelength-converting layer 540 may be applied across the surface of the wafer 600 (7B). For some embodiments, the entire surface of the wafer 600 including the n-contacts 530 may be covered. Again, the wavelength-converting layer 540 may comprise a first transparent layer formed above the surface of the n-type semiconductor region 514 and a second layer with the phosphor and a binding material formed above the first layer.

A temporary protective layer 750, such as a photoresist, may be applied using any suitable means, such as lithography, on the wavelength-converting layer 540 (7C). For some embodiments, the protective layer 750 may be applied on the entire surface of the wavelength-converting layer 540, and the protective layer 750 may be removed or opened up in regions above the n-contacts 530. In other embodiments, the protective layer 750 may be applied to the surface of the wavelength-converting layer 540 everywhere except in regions above the n-contacts 530.

After the protective layer 750 has been applied and treated as necessary, the wavelength-converting layer 540 on and above the n-contacts 530 may be removed by any suitable method, such as wet etching or dry etching (7D). After portions of the wavelength-converting layer 540 have been removed, the protective layer 750 may be removed altogether (7E). Then, the LED die on the wafer 600 may be diced and separated into individual components (7F).

### Exemplary Wavelength-Converting Layer Formation Methods At the Die Level

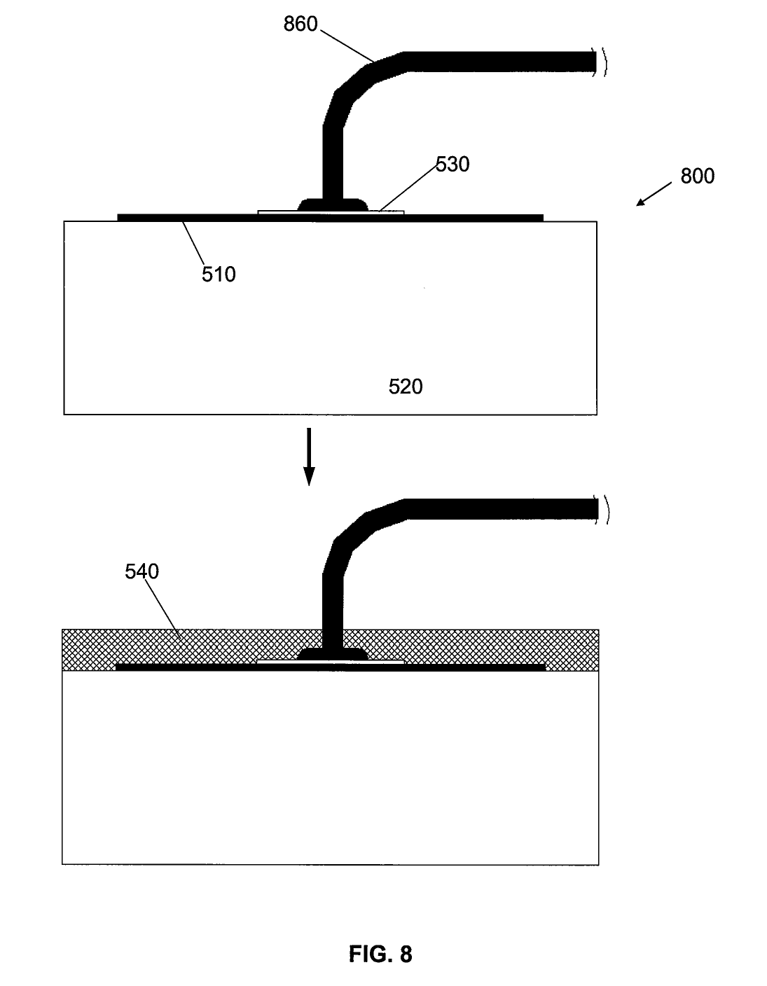

Now that methods of forming the wavelength-converting layer 540 at the wafer level have been described, methods of forming the wavelength-converting layer 540 at the individual die level will be discussed. FIG. 8 illustrates a method of forming the wavelength-converting layer 540 on an individual LED device 800 after the wafer 600 has been diced and separated. The LED device 800 may have the LED semiconductor structure 510, metal substrate 520, and n-contact 530 described above. In addition, a lead wire 860 may be bonded to the n-contact 530 to provide an external electrical connection for the LED device 800.

After the addition of the lead wire 860, the wavelength-converting layer 540 may be formed according to different methods. For some embodiments, the wavelength-converting material may be applied by spray coating the top surface of the semiconductor structure 510 to form the wavelength-converting layer 540. In other embodiments, the wavelength-converting material may be dispensed as one or more drops on the surface of the semiconductor structure 510 and allowed to spread. In either case, the wavelength-converting layer 540 may be baked to evaporate the moisture content of the phosphor mixed with the binding material.

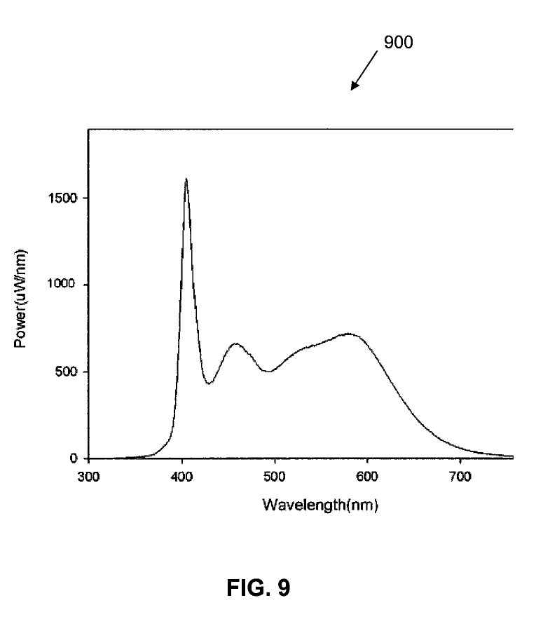

Although a single phosphor is described above, multiple fluorescent components may be employed in the wavelength-converting layer 540. Multiple phosphor components may produce a multi-peak wavelength spectrum. FIG. 9 illustrates an example spectrum 900 of a forward-biased LED device with a wavelength-converting layer 540 comprising multiple phosphor components.

### Exemplary Methods for Using a Pre-Fabricated Wavelength-Converting Layer

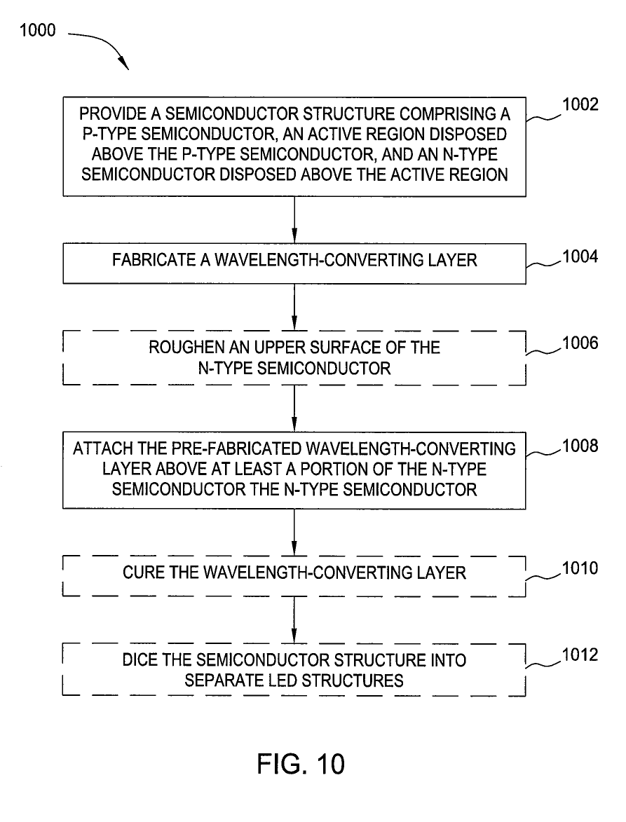

FIG. 10 is a flow diagram of example operations 1000 for attaching a pre-fabricated wavelength-converting layer to a semiconductor structure. The operations 1000 may begin, at 1002, by providing a semiconductor structure. The semiconductor structure may be a wafer, such as the semiconductor structure 510 of FIG. 5, or an individual LED die after dicing a wafer. The semiconductor structure may comprise a p-type semiconductor (e.g., p-type region 512), an active region (e.g., active region 513) disposed above the p-type semiconductor, and an n-type semiconductor (e.g., n-type region 514) disposed above the active region.

At 1004, a wavelength-converting layer may be fabricated. The wavelength-converting layer may be similar in size, composition, purpose, and/or features (e.g., patterning) to wavelength-converting layer 540 described above. For example, the wavelength-converting layer may have substantially equal thickness, a flat surface, and a rectangular cross-section.

However, the wavelength-converting layer is not fabricated on the surface of the wafer or the LED die for this embodiment. Rather, this wavelength-converting layer is manufactured separate from the semiconductor structure using any of various suitable techniques. These techniques may include mixing a phosphor powder with a binding material (e.g., silicone, epoxy, acrylic, or spin-on glass) according to a certain ratio and then applying the resulting mixture to a substrate. Application of the mixture to a substrate may comprise coating the substrate using any of various suitable coating techniques, such as gravure coating, reverse roll coating, knife over roll coating (also known as “gap coating), metering rod coating (also known as meyer rod or meyer bar coating), slot die coating (e.g., extrusion), immersion coating (e.g., dipping), curtain coating, or air knife coating. Application of the mixture to the substrate may also comprise screen printing, dispensing, spray coating, inject printing, a roller method, or a dipping method.

After applying the mixture to the substrate, the mixture may be cured or baked in an effort to harden the mixture. The curing method is not limited as long as the moisture content of the wavelength-converting material is evaporated. Thus, various methods using a heater, an oven, dried air, or surface treatment such as a radiant heat lamp may be employed. After curing, the wavelength-converting layer may be patterned in an effort to increase light extraction. For some embodiments, the cured mixture may be separated from the substrate (e.g., by removing the substrate) to form the pre-fabricated wavelength-converting layer.

For some embodiments, the wavelength-converting layer may be cut to match the size of the wafer, an individual LED die, or a group of LED dies. Such cutting of the wavelength-converting layer may be accomplished by any of various suitable methods including using a laser, a knife (e.g., an air knife), or a dicing saw.

At 1008, the pre-fabricated wavelength-converting layer may be attached above at least a portion of the n-type semiconductor. Attaching the pre-fabricated wavelength-converting layer comprises using any of various suitable attachment materials, such as at least one of glue, silicone, epoxy, spin-on glass, and a pressure-sensitive adhesive (PSA). The attachment material (e.g., glue or adhesive) may be applied to a surface of the wavelength-converting layer, to an exposed surface of the n-type semiconductor, or to both before attachment. The attachment material may be applied via any of various suitable techniques including dispensing, spraying on, or coating the surface(s) with the material.

For some embodiments, the wavelength-converting layer may only cover the top of the at least the portion of the n-type semiconductor. In other words, the wavelength-converting layer does not cover lateral surfaces of the n-type semiconductor, the active region, or the p-type semiconductor.

For some embodiments as an option, an upper surface of the n-type semiconductor may be roughened at 1006 before attaching the pre-fabricated wavelength-converting layer, in an effort to improve light extraction. The roughening of the surface of the n-type semiconductor may be accomplished using any suitable method, including wet etching, dry etching, and photolithography with etching.

For some embodiments, the wavelength-converting layer may be cured at 1010 after attaching this layer at 1008. Curing the structure resulting from attachment of the wavelength-converting layer may harden the attachment material (e.g., silicone or epoxy) and remove any moisture therefrom.

At 1012, the semiconductor structure may be diced into separate LED structures in embodiments where the semiconductor structure comprises a wafer, for example. For other embodiments, the semiconductor structure already comprises an LED die, so dicing need not be performed after attachment of the wavelength-converting layer.

While the foregoing is directed to embodiments of the present invention, other and further embodiments of the invention may be devised without departing from the basic scope thereof, and the scope thereof is determined by the claims that follow.

1. A method for fabricating a light-emitting diode (LED) structure, comprising:
providing a semiconductor structure comprising:
a p-type semiconductor;
an active region disposed above the p-type semiconductor; and
an n-type semiconductor disposed above the active region; and
attaching a pre-fabricated wavelength-converting layer above at least a portion of the n-type semiconductor.

2. The method of claim 1, wherein attaching the wavelength-converting layer comprises using at least one of glue, silicone, epoxy, spin-on glass, and a pressure-sensitive adhesive (PSA).

3. The method of claim 1, wherein the wavelength-converting layer has a rectangular cross-section.

4. The method of claim 1, wherein the wavelength-converting layer has a substantially equal thickness.

5. The method of claim 1, wherein after the attaching, an upper surface of the wavelength-converting layer is substantially flat.

6. The method of claim 1, wherein the wavelength-converting layer comprises a first transparent layer and applying a second layer comprising at least a phosphor and a binding material.

7. The method of claim 6, wherein the first transparent layer comprises at least one of silicon dioxide, silicon nitride, titanium oxide, aluminum oxide, indium tin oxide (ITO), and polymer materials.

8. The method of claim 1, wherein the wavelength-converting layer is patterned.

9. The method of claim 1, wherein the wavelength-converting layer comprises at least a phosphor and a binding material.

10. The method of claim 1, further comprising roughening an upper surface of the n-type semiconductor before attaching the wavelength-converting layer by at least one of wet etching, dry etching, and photolithography with etching.

11. The method of claim 1, further comprising curing the wavelength-converting layer after the attaching.

12. The method of claim 1, further comprising depositing an n-contact on a surface of the n-type semiconductor.

13. The method of claim 12, further comprising bonding, to the n-contact, a wire for external connection.

14. The method of claim 1, wherein the p-type semiconductor is disposed above one or more metal layers.

15. The method of claim 1, further comprising dicing the semiconductor structure into separate LED structures.

16. A light emitting diode (LED) structure, comprising:
a p-type semiconductor;
an active region disposed above the p-type semiconductor;
an n-type semiconductor disposed above the active region; and
a wavelength-converting layer disposed above at least a portion of the n-type semiconductor, wherein an upper surface of the wavelength-converting layer is substantially flat.

17. The LED structure of claim 16, wherein the wavelength-converting layer has a rectangular cross-section.

18. The LED structure of claim 16, wherein the wavelength-converting layer has a substantially equal thickness.

19. The LED structure of claim 16, wherein the wavelength-converting layer is attached to the at least the portion of the n-type semiconductor with at least one of glue, silicone, epoxy, spin-on glass, and a pressure-sensitive adhesive (PSA).

20. The LED structure of claim 16, wherein the wavelength-converting layer does not cover lateral surfaces of the n-type semiconductor, the active region, or the p-type semiconductor.

21. The LED structure of claim 16, wherein the wavelength-converting layer comprises a first transparent layer and a second layer comprising at least a phosphor and a binding material.

22. The LED structure of claim 21, wherein the first transparent layer comprises at least one of silicon dioxide, silicon nitride, titanium oxide, aluminum oxide, indium tin oxide (ITO), and polymer materials.

23. The LED structure of claim 16, wherein the wavelength-converting layer is patterned.

24. The LED structure of claim 16, wherein the wavelength-converting layer comprises at least a phosphor and a binding material.

25. The LED structure of claim 24, wherein the binding material comprises silicone, epoxy, or spin-on glass.

26. The LED structure of claim 16, further comprising an n-contact disposed above a surface of the n-type semiconductor.

27. The LED structure of claim 26, further comprising a wire bonded to the re-contact for external connection.

28. The LED structure of claim 16, wherein the p-type semiconductor is disposed above one or more metal layers.

29. A light emitting diode (LED) structure, comprising:
one or more metal layers;
a p-type semiconductor coupled to the metal layers;
an active region coupled to the p-type semiconductor;
an n-type semiconductor coupled to the active region; and
a wavelength-converting layer coupled to at least a portion of the n-type semiconductor.

30. The LED structure of claim 29, wherein the metal layers comprise a metal or metal alloy of at least one of copper, nickel, and aluminum.

31. The LED structure of claim 29, wherein the p-type semiconductor comprises p-GaN.

32. The LED structure of claim 29, wherein the active region emits a light having a wavelength between 200 nm and 480 nm when forward biased.

33. The LED structure of claim 29, wherein the active region comprises AlₓIn_{y}Ga_{1-x-y}N, where 0≦x≦1 and 0≦y≦1−x.

34. The LED structure of claim 29, wherein the n-type semiconductor comprises n-GaN.

35. The LED structure of claim 29, wherein the wavelength-converting layer comprises a phosphor and a binding material.

36. The LED structure of claim 35, wherein the binding material comprises silicone, epoxy, or spin-on glass

37. The LED structure of claim 29, wherein the wavelength-converting layer comprises a first transparent layer and a second layer comprising at least a phosphor and a binding material, wherein the first transparent layer is coupled to the n-type semiconductor, and wherein the second layer is coupled to the first transparent layer.

38. The LED structure of claim 37, wherein the first transparent layer comprises at least one of silicon dioxide, silicon nitride, titanium oxide, aluminum oxide, indium tin oxide (ITO), and polymer materials.

39. The LED structure of claim 37, wherein the binding material comprises at least one of silicone, epoxy, acrylic, and spin-on glass.

40. The LED structure of claim 29, wherein the wavelength-converting layer is patterned.

41. The LED structure of claim 29, wherein the wavelength-converting layer is substantially conformal.

42. The LED structure of claim 29, wherein the wavelength-converting layer is flat and substantially congruent to the n-type semiconductor.

43. A light emitting diode (LED) structure, comprising:
a p-type semiconductor;
an active region disposed above the p-type semiconductor;
an n-type semiconductor disposed above the active region; and
a substantially flat phosphor layer disposed above at least a portion of the n-type semiconductor.

44. The LED structure of claim 43, wherein the substantially flat phosphor layer is attached to the LED structure using at least one of glue, silicone, epoxy, spin-on glass, and a pressure-sensitive adhesive (PSA).

45. The LED structure of claim 43, wherein the substantially flat phosphor layer has a rectangular cross-section.

46. The LED structure of claim 43, wherein the substantially flat phosphor layer comprises:
a first transparent layer; and
a second layer comprising at least a phosphor and a binding material.

47. The LED structure of claim 46, wherein the first transparent layer comprises at least one of silicon dioxide, silicon nitride, titanium oxide, aluminum oxide, indium tin oxide (ITO), and polymer materials.

48. The LED structure of claim 43, wherein the substantially flat phosphor layer is patterned.

49. The LED structure of claim 43, wherein an upper surface of the n-type semiconductor is roughened.

50. The LED structure of claim 43, wherein the substantially flat phosphor layer has been cured before and after attaching the substantially flat phosphor layer to the LED structure.

51. The LED structure of claim 43, further comprising an n-contact disposed above a surface of the n-type semiconductor.
